(19) United States
(12) Patent Application Publication
(10) Pub. No.: US 2026/0293226 A1
(43) Pub. Date: Sep. 24, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Takahiro KATO, Nonoichi Ishikawa (JP); Yoko IWAKAJI, Meguro Tokyo (JP); Kenichi MATSUSHITA, Nonoichi Ishikawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/300,453

(22) Filed: Aug. 14, 2025

(30) Foreign Application Priority Data
Mar. 18, 2025 (JP) 2025-043901
May 15, 2025 (JP) 2025-081926

(51) Int. Cl. H10D 62/10; H10D 8/00; H10D 12/00; H10D 84/00

(52) U.S. Cl. CPC H10D 62/107; H10D 8/422; H10D 12/481; H10D 84/161

(57) ABSTRACT

According to one embodiment, a semiconductor layer has a first surface and a second surface opposite to the first surface. The semiconductor layer has a first region, a second region, a third region, and a fifth region. The first region is provided between the first and second surfaces of the semiconductor layer and has a first conductivity type. The second region is electrically connected to the first electrode, is provided between a first surface side surface of the first region and a second surface side surface of the first region, and has a second conductivity type. A distance from the top surface of the second region to the first electrode is set to be longer than a distance from the first surface side surface of the first region to the first electrode.

### CROSS-REFERENCETORELATEDAPPLICATIONS

This application is based upon and claims the benefit of priority from the prior Japanese Patent Applications No. 2025-043901, filed on March 18, 2025, and No. 2025-081926, filed on May 15, 2025 the entire contents of which are incorporated herein by reference.

### FIELD

The embodiments of the present invention relate to a semiconductor device.

### BACKGROUND

There is known a reverse conducting IGBT (RC-IGBT: Reverse Conducting Insulated Gate Bipolar Transistor) as one semiconductor device including a transistor and a freewheeling diode connected to the transistor in anti-parallel. In such a semiconductor device, the transistor is formed in a transistor region, and the diode is formed in a diode region, in general. When the diode in the diode region becomes conductive, an electron current flows from a cathode region to an anode region in the diode region, and a hole current flows from the anode region.

However, during reverse recovery of the diode, holes may also be injected from the transistor region. Accordingly, the time until carriers are eliminated during reverse recovery of the diode may become long.

### BRIEF DESCRIPTION OF THE DRAWINGS

FIG. 1 is a schematic top view of a semiconductor device according to the present embodiment;

FIG. 2 is a cross-sectional view taken along a line A-A’ in FIG. 1;

FIG. 3A is a diagram illustrating a region of an A-A’ cross-section in a case where a depletion layer generation region is not included as a comparative example;

FIG. 3B is a diagram illustrating the region of the A-A’ cross-section in a case where the depletion layer generation region is included;

FIG. 4 is a graph illustrating hole densities on lines in FIGS. 3A and 3B;

FIG. 5A is a cross-sectional view taken along the line A-A’ in FIG. 1 according to a second embodiment;

FIG. 5B is a cross-sectional view taken along the line A-A’ in FIG. 1 according to a first modification of the second embodiment;

FIG. 6 is a cross-sectional view taken along the line A-A’ in FIG. 1 according to a third embodiment;

FIG. 7 is a cross-sectional view taken along a line B-B’ in FIG. 1 according to the third embodiment; and

FIG. 8 is a cross-sectional view parallel to the cross-sectional view taken along the line B-B’.

### DETAILED DESCRIPTION

According to one embodiment, a semiconductor device including a transistor region and a diode region comprises a semiconductor layer, a first electrode, and a second electrode. The semiconductor layer has a first surface and a second surface opposite to the first surface. The first electrode is provided on the first surface. The second electrode is provided on the second surface. The semiconductor layer includes a first region, a second region, a third region, and a fifth region. The first region has a first conductivity type provided between the first surface and the second surface of the semiconductor layer. The second region has a second conductivity type electrically connected to the first electrode and provided between a first surface side surface of the first region and a second surface side surface of the first region, a distance between a first surface side surface of the second region and the first electrode being longer than a distance between the first surface side surface of the first region and the first electrode. The third region has the second conductivity type provided between the first surface side surface of the first region and the first electrode. The fifth region has the first conductivity type electrically connected to the first electrode and provided between the third region and the first surface.

Embodiments of the present disclosure will be explained below with reference to the drawings. In the following descriptions, identical or similar members are denoted by like reference characters and explanations of members having been described once are omitted as appropriate.

In the present specification, when the terms n⁺-type, n-type, and n⁻-type are used, the terms mean that the n-type impurity concentration decreases in the order of n⁺-type, n-type, and n⁻-type. Further, when the terms p⁺-type, p-type, and p⁻-type are used, the terms mean that the p-type impurity concentration decreases in the order of p⁺-type, p-type, and p⁻-type.

In the present specification, the distribution and the absolute value of the impurity concentration in a semiconductor region can be measured by secondary ion mass spectrometry (SIMS), for example. The relative magnitude relation between the impurity concentrations in two semiconductor regions can be determined using scanning capacitance microscopy (SCM), for example. Further, the distribution and the absolute value of the impurity concentration can be measured using spreading resistance analysis (SRA), for example. In the SCM and the SRA, the relative magnitude relation between the carrier concentrations in the semiconductor regions and the absolute value of the carrier concentration in the semiconductor region are obtained. By assuming the activation rate of impurity, it is possible to obtain the relative magnitude relation between the impurity concentrations of the two semiconductor regions, the distribution of the impurity concentration, and the absolute value of the impurity concentration from the measurement results of the SCM and the SRA.

### First Embodiment

A semiconductor device 100 according to a first embodiment is an RC-IGBT in which an IGBT and a diode are formed on the same semiconductor chip, for example.

The semiconductor device 100 according to the present embodiment includes a trench gate IGBT having a gate electrode in a trench formed in a semiconductor layer. A case where a first conductivity type is the n-type and a second conductivity type is the p-type is described below as an example. However, the first conductivity type and the second conductivity type may be the p-type and the n-type, respectively. In this case, conductivity types of a substrate, a layer, a region, and the like in each embodiment have reverse polarities.

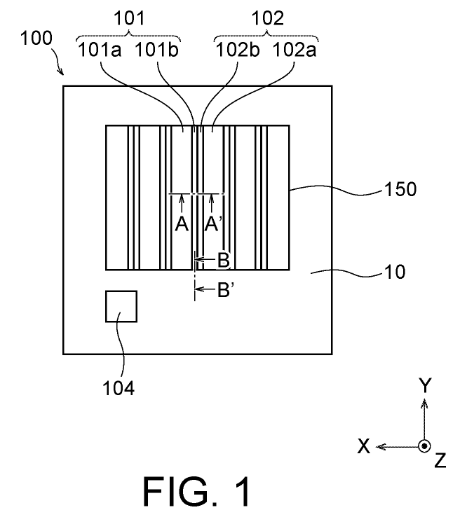

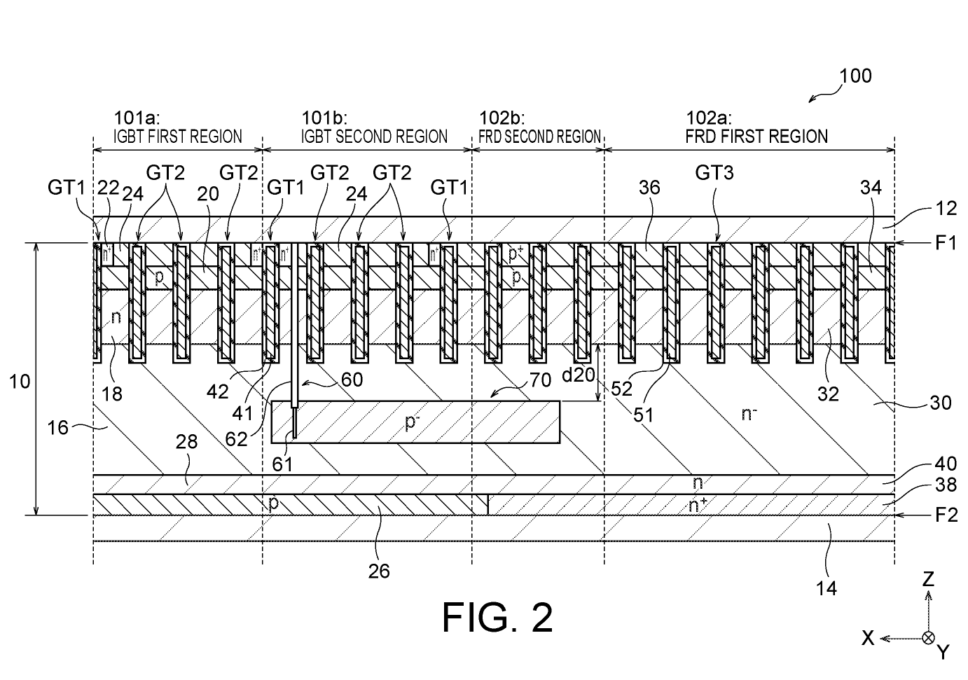

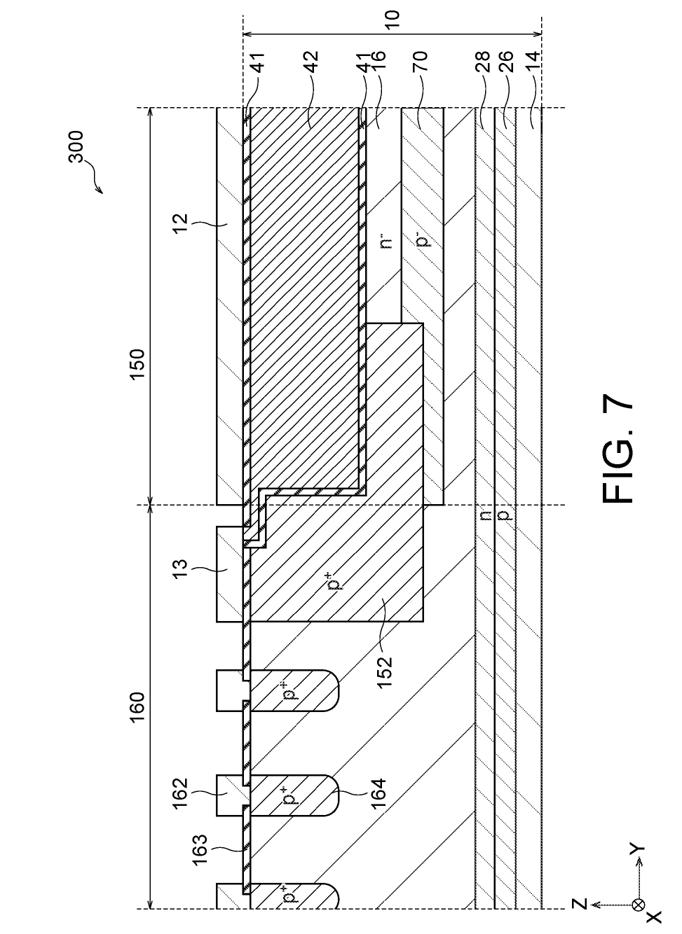

FIG. 1 is a schematic top view of the semiconductor device 100 according to the present embodiment. FIG. 2 is a cross-sectional view taken along a line A-A’ in FIG. 1. A cross-section taken along a line B-B’ will be described later with reference to FIG. 7.

In the present specification, technical matters may be described using orthogonal coordinate axes of an x-axis, a y-axis, and a z-axis. In the present specification, an x-direction parallel to a first surface F1 of a semiconductor layer 10 is referred to as a first direction. A y-direction parallel to the first surface F1 and perpendicular to the first direction is referred to as a second direction. A z-direction towards the first surface F1 from a second surface F2, which is perpendicular to the x- and y-directions, is referred to as a third direction.

The semiconductor device 100 according to the present embodiment includes the semiconductor layer 10 (see FIG. 2). In an active region part 150 of the semiconductor layer 10, a transistor region 101 and a diode region 102 extend in the second direction and are alternately arranged (see FIG. 1). In a peripheral region part 160 of the active region part 150, a gate wire electrically connected to a first gate electrode pad 104 and a guard ring are arranged, although the gate wire and the guard ring are not illustrated. The semiconductor device 100 according to the present embodiment is a device that can reduce the hole accumulation amount in a boundary region in a diode mode, and has the transistor region 101, the diode region 102, and the first gate electrode pad 104.

The transistor region 101 includes a first transistor region (IGBT first region) 101a and a second transistor region (IGBT second region) 101b. The diode region 102 includes a first diode region (FRD first region) 102a and a second diode region (FRD second region) 102b. The second transistor region 101b and the second diode region 102b serve as the boundary region.

The transistor region 101 is a region where an IGBT is formed as a transistor. That is, the transistor region 101 operates as the IGBT.

The diode region 102 is a region where a diode is formed. The diode region 102 operates as a freewheeling diode, for example. The freewheeling diode is a Fast Recovery Diode (FRD), for example.

The second transistor region 101b as the boundary region of the IGBT is provided between the first transistor region 101a and the diode region 102. The second diode region 102b as the boundary region of the FRD is provided between the transistor region 101 and the first diode region 102a. The total width in the first direction of the second transistor region 101b and the second diode region 102b serving as the boundary region is approximately the same as the length of diffusion of holes from the transistor region 101 to the diode region 102, for example, during an operation of the diode region 102. A first range is assumed as the length in the first direction of diffusion of holes from the transistor region 101 during the operation of the diode region 102. At this time, the second transistor region 101b and the second diode region 102b are each located within the first range from the boundary between the transistor region 101 and the diode region 102.

As illustrated in FIG. 2, the semiconductor layer 10 has a layered structure whose conductivity type is common to that of the transistor region 101 and the diode region 102. That is, the semiconductor layer 10 includes a first drift region 16 and a second drift region 30 (first region), a depletion layer generation region 70 (second region), a base region 20 and an anode region 34 (third region), a barrier region 18 and a second barrier region 32 (fourth region), and buffer regions 28 and 40.

The transistor region 101 further includes a cell emitter region 22 (fifth region), a cell contact region 24 and a collector region 26 (sixth region), a first trench GT1, and a second trench GT2. Meanwhile, the diode region 102 further includes a diode contact region 36 (seventh region), a cathode region 38 (eighth region), and a third trench GT3.

A configuration example of the transistor region 101 is described here. In more detail, the semiconductor layer 10 has the first surface F1 and the second surface F2 opposite to the first surface F1. The semiconductor layer 10 is a layer of monocrystalline silicon, for example. The thickness of the semiconductor layer 10 is 40 μm or more and 700 μm or less, for example.

An upper electrode 12 is provided on the first surface F1 side of the semiconductor layer 10. At least a portion of the upper electrode 12 is in contact with the first surface F1 of the semiconductor layer 10.

The upper electrode 12 serves as an emitter electrode of the IGBT in the transistor region 101. The upper electrode 12 is made of metal, for example. That is, the upper electrode 12 is electrically connected to the cell emitter region 22. The cell emitter region 22 is an n⁺-type semiconductor region.

A lower electrode 14 is provided on the second surface F2 side of the semiconductor layer 10. At least a portion of the lower electrode 14 is in contact with the second surface F2 of the semiconductor layer 10. That is, the lower electrode 14 is electrically connected to the collector region 26. The collector region 26 is a p-type semiconductor region.

The lower electrode 14 serves as a collector electrode of the IGBT in the transistor region 101. The lower electrode 14 is made of metal, for example. The collector region 26 serves as a source of holes while the IGBT is in an on state.

The first drift region 16 is an n⁻-type semiconductor region. The first drift region 16 is provided between the barrier region 18 and the first buffer region 28 in the transistor region 101.

The first drift region 16 serves as a path of an on-current while the IGBT is in an on state. The first drift region 16 has a function of being depleted to maintain the breakdown voltage of the IGBT while the IGBT is in an off state.

The barrier region 18 is an n-type semiconductor region. The barrier region 18 is provided between the first drift region 16 and the base region 20.

The barrier region 18 contains an n-type impurity the concentration of which is higher than the n-type impurity concentration in the first drift region 16. The barrier region 18 contains the n-type impurity concentration which is lower than the n-type impurity concentration in the cell emitter region 22. By providing the barrier region 18, a potential barrier against holes becomes high between the first drift region 16 and the base region 20, so that movement of the holes to the base region 20 can be suppressed. Accordingly, the electron density and the hole density in the first drift region 16 in a conductive state become high, and the on voltage can be lowered.

The base region 20 is a p-type semiconductor region. The base region 20 is provided between the first drift region 16 and the cell emitter region 22 and between the first drift region 16 and the cell contact region 24.

The cell emitter region 22 is an n⁺-type semiconductor region. The cell emitter region 22 is provided between the base region 20 and the first surface F1. The cell emitter region 22 is in contact with a first gate dielectric film 42. The depth of the base region 20 is 5 μm or less, for example. In a region of the base region 20, which faces a third electrode 41, an n-type inversion layer is formed while the IGBT is in an on state. That is, the base region 20 serves as a channel region of the transistor.

The cell emitter region 22 is formed to have an n-type impurity concentration higher than that of the first drift region 16. The cell emitter region 22 is electrically connected to the upper electrode 12. The cell emitter region 22 serves as a source of electrons while the transistor including the third electrode 41 is in an on state.

The cell contact region 24 is a p⁺-type semiconductor region. The cell contact region 24 is provided between the base region 20 and the first surface F1. The collector region 26 is a p-type semiconductor region.

The first buffer region 28 is an n-type buffer layer, for example. The first buffer region 28 is formed to have an n-type impurity concentration higher than that of the first drift region 16. The first buffer region 28 is provided between the first drift region 16 and the collector region 26. The first buffer region 28 serves as a layer that prevents a depletion layer spreading from the lower surface side of the base region 20 from reaching the collector region 26.

The first trench GT1 is provided in the first surface F1 side part of the semiconductor layer 10. The first trench GT1 is a groove provided in the semiconductor layer 10. The first trench GT1 is a portion of the semiconductor layer 10. The first trench GT1 penetrates through the base region 20 and reaches the first drift region 16.

In the first surface F1, the first trench GT1 extends in the second direction parallel to the first surface F1. The first trench GT1 has a stripe shape. The plural first trenches GT1 are arranged repeatedly in the first direction perpendicular to the second direction.

Each first trench GT1 is in contact with the first drift region 16, the barrier region 18, the base region 20, and the cell emitter region 22.

The third electrode 41 is a gate electrode and is provided in the first trench GT1. The third electrode 41 is formed to contain conductive polysilicon containing an impurity, for example. The third electrode 41 is electrically connected to the first gate electrode pad 104.

The first gate dielectric film 42 is provided between the third electrode 41 and the semiconductor layer 10 and between the third electrode 41 and the upper electrode 12. That is, the first gate dielectric film 42 is provided between the third electrode 41 and the upper electrode 12, between the third electrode 41 and the first drift region 16, between the third electrode 41 and the barrier region 18, between the third electrode 41 and the base region 20, and between the third electrode 41 and the cell emitter region 22. The first gate dielectric film 42 is made of silicon oxide, for example.

The second trench GT2 has a configuration equivalent to that of the first trench GT1. That is, the second trench GT2 is in contact with the first drift region 16, the barrier region 18, the base region 20, and the cell emitter region 22. The second trench GT2 penetrates through the base region 20 and reaches the first drift region 16.

The third electrode 41 in the second trench GT2 is a dummy electrode and is at an emitter potential, for example. Alternatively, the potential of this third electrode 41 can be set to a floating potential.

A first trench contact 60 is provided in the first surface F1 side part of the semiconductor layer 10 in at least either one of the second transistor region 101b and the second diode region 102b. The first trench contact 60 is a portion of the semiconductor layer 10.

The first trench contact 60 includes a conductive region 61 and a trench insulation film 62. In the first surface F1, the first trench contact 60 extends in the second direction parallel to the first surface F1. The first trench contact 60 has a stripe shape.

The conductive region 61 of the first trench contact 60 is electrically connected to the upper electrode 12. The second surface F2 side end of the conductive region 61 is electrically connected to the depletion layer generation region 70. The material for the conductive region 61 may be different from the material for the upper electrode 12. Alternatively, the material for the conductive region 61 may be the same as the material for the upper electrode 12. That is, the conductive region 61 is made of a material containing a metal. Alternatively, the conductive region 61 may contain conductive polysilicon with an impurity added thereto, for example.

The trench insulation film 62 is made of silicon oxide, for example. The trench insulation film 62 is provided between the first trench contact 60 and the semiconductor layer 10. That is, the trench insulation film 62 is provided between the conductive region 61 and the first drift region 16, between the first trench contact 60 and the barrier region 18, between the conductive region 61 and the base region 20, and between the conductive region 61 and the cell emitter region 22 or the cell contact region 24.

The depletion layer generation region 70 extends in the second direction parallel to the first surface F1. The depletion layer generation region 70 is a p⁻-type semiconductor region. The depletion layer generation region 70 desirably contains a p-type impurity whose concentration is lower than the p-type impurity concentration in the base region 20.

The depletion layer generation region 70 is electrically connected to the upper electrode 12 and is provided between the first surface F1 side surface of the first region and the second surface F2 side surface of the first region with a predetermined distance d20 from the first surface F1 side surfaces of the first drift region 16 and the second drift region 30. The first drift region 16, which is an n⁻-type semiconductor region, is in contact with the first surface F1 side of the depletion layer generation region 70. That is, the depletion layer generation region 70 is arranged in such a manner that the distance from its top surface to the upper electrode 12 is longer than the distance to the upper electrode 12 from the first surface F1 side surfaces of the first drift region 16 and the second drift region 30.

In a diode mode, the depletion layer generation region 70 is at an anode potential of the diode region 102. Therefore, the pn junction between the depletion layer generation region 70 being a p⁻-type semiconductor region and the first drift region 16 being an n⁻-type semiconductor region in contact with the first surface F1 side of the depletion layer generation region 70 is reverse biased. Accordingly, in the diode mode, a depletion layer is generated on the first surface F1 side of the depletion layer generation region 70, and the inflow of the depletion layer from the transistor region 101 side to the diode region 102 side is suppressed.

Further, due to the presence of at least either one of the first drift region 16 and the second drift region 30 between the depletion layer generation region 70, and the barrier region 18 and the second barrier region 32, the depletion layer can easily extend, so that the effect of suppressing hole injection can be enhanced. Furthermore, by lowering the p-type impurity concentration in the depletion layer generation region 70, influence on accumulation of carriers for conductivity modulation can be reduced, and influence on the on-operation of IGBT, for example, increase in the on-voltage can be suppressed.

As described above, in the diode mode, the hole accumulation amount in the boundary region is reduced compared to the related art, and therefore recovery loss (Err) can be reduced. In this case, a range in the third direction within which the depletion layer is generated can be adjusted by adjusting the predetermined distance d20 described above.

Although the depletion layer generation region 70 according to the present embodiment is arranged in the second transistor region 101b and the second diode region 102b, the arrangement is not limited thereto. For example, the depletion layer generation region 70 can be arranged in either one of the second transistor region 101b and the second diode region 102b. In this case, the first trench contact 60 can be arranged in at least either one of the second transistor region 101b and the second diode region 102b.

The configuration example of the transistor region 101 according to the present embodiment is only an example, and the configuration of the transistor region 101 is not limited thereto. For example, a configuration not including the barrier region 18 can be employed. Alternatively, the cell emitter region 22 can be provided in place of the cell contact region 24.

A configuration example of the diode region 102 is described here. In the semiconductor layer 10 of the diode region 102, the second drift region 30, the second barrier region 32, the anode region 34, the diode contact region 36, the cathode region 38, the second buffer region 40, and a fourth electrode 51 are provided.

The upper electrode 12 serves as an anode electrode of a diode in the diode region 102. The upper electrode 12 is electrically connected to the diode contact region 36. The upper electrode 12 is also electrically connected to the anode region 34 via the diode contact region 36. Alternatively, the upper electrode 12 may be in direct contact with the anode region 34. In this case, the upper electrode 12 and the anode region 34 have a Schottky junction therebetween, for example.

The lower electrode 14 serves as a cathode electrode of the diode in the diode region 102. The lower electrode 14 is in contact with the cathode region 38.

The second drift region 30 is provided between the second barrier region 32 and the second buffer region 40 in the diode region 102. The second drift region 30 is an n⁻-type semiconductor region. In the third direction (z-direction), the second drift region 30 has a thickness equivalent to that of the first drift region 16. The second barrier region 32 is an n-type semiconductor region.

The second drift region 30 is formed to have an n-type impurity concentration lower than that of the cathode region 38. The second drift region 30 serves as a path of an on-current while the diode is in an on state.

The diode contact region 36 is a p⁺-type semiconductor region. The diode contact region 36 is provided between the anode region 34 and the first surface F1.

The diode contact region 36 is in contact with the upper electrode 12. The diode contact region 36 is electrically connected to the upper electrode 12. The diode contact region 36 is formed to have a p-type impurity concentration higher than that of the anode region 34.

The cathode region 38 is an n⁺-type semiconductor region. The cathode region 38 is in contact with the second surface F2. The cathode region 38 serves as a source of electrons while the diode is in an on state. The cathode region 38 is in contact with the lower electrode 14.

The anode region 34 is a p-type semiconductor region. The anode region 34 is provided between the second drift region 30 and the diode contact region 36. The anode region 34 serves as a source of holes while the diode is in an on state. The depth of the anode region 34 is the same as that of the base region 20, for example.

In the third direction, the second buffer region 40 has a thickness equivalent to that of the first buffer region 28. The second buffer region 40 is formed to have an n-type impurity concentration higher than that of the second drift region 30. The second buffer region 40 is provided between the second drift region 30 and the cathode region 38 in the third direction. For example, the second buffer region 40 serves as a layer that prevents a depletion layer spreading from the lower surface side of the base region 20 from reaching the cathode region 38.

The third trench GT3 is provided in the first surface F1 side part of the semiconductor layer 10 to be in contact with the anode region 34. The third trench GT3 is a groove provided in the semiconductor layer 10. The third trench GT3 is a portion of the semiconductor layer 10.

In the first surface F1, the third trench GT3 extends in the second direction parallel to the first surface F1. The third trench GT3 has a stripe shape. The plural third trenches GT3 are arranged repeatedly in the first direction perpendicular to the second direction.

The fourth electrode 51 is provided in the third trench GT3. The fourth electrode 51 is formed to contain conductive polysilicon containing an impurity, for example. The third trench GT3 places the fourth electrode 51 at the anode potential, for example. Alternatively, it is also possible not to fix that potential to a specific potential. A diode insulation film 52 is arranged to encompass the third trench GT3.

An operation example of the semiconductor device 100 is described here. A predetermined first gate voltage is applied to the first gate electrode pad 104 at a predetermined timing. After a first turn-on voltage is applied to the first gate electrode pad 104, a predetermined first turn-off voltage is applied to the first gate electrode pad 104.

An emitter voltage is applied to the upper electrode 12 in the transistor region 101. The emitter voltage is 0 V, for example. A collector voltage is applied to the lower electrode 14. The collector voltage is 200 V or more and 6500 V or less, for example.

While the IGBT is in an off state, the first turn-off voltage is applied to the first gate electrode pad 104. Therefore, the first turn-off voltage is also applied to the third electrode 41. The first turn-off voltage is a voltage lower than a threshold voltage at which the transistor including the third electrode 41 is not turned on, for example, 0 V or a negative voltage. While the IGBT is in an off state, an n-type inversion layer is not formed in a portion of the base region 20 which faces the third electrode 41 and is in contact with the first gate dielectric film 42.

Meanwhile, when the first turn-on voltage is applied to the first gate electrode pad 104, the first gate voltage becomes the first turn-on voltage, and the first turn-on voltage is also applied to the third electrode 41. By application of the first turn-on voltage, the transistor including the third electrode 41 is turned on. While the transistor is in an on state, an n-type inversion layer is formed in the portion of the base region 20 which faces the third electrode 41 and is in contact with the first gate dielectric film 42. Accordingly, the IGBT becomes conductive.

Meanwhile, when the first turn-off voltage is applied to the third electrode 41, and the diode region 102 becomes conductive, an electron current flows from the cathode region 38 to the anode region 34, and a hole current flows from the anode region 34.

In a case where the depletion layer generation region 70 is not provided, the base region 20 of the transistor region 101 is at the same potential as that of the anode region 34. Therefore, holes from the transistor region 101 are also injected into the first diode region (FRD first region) 102a and the second diode region (FRD second region) 102b. Therefore, the hole density in the semiconductor layer 10 increases. Accordingly, the time until carriers are eliminated when the diode in the diode region 102 is turned off becomes long.

In the diode mode, a current flows from the first surface F1 side toward the second surface F2 (downward in the drawing). In a case where the depletion layer generation region 70 according to the present embodiment is provided, a diode is formed in the first surface F1 side surface of the depletion layer generation region 70, the forward direction of which is opposite to the direction of a current in the diode mode (downward in the drawing). Accordingly, the current that tends to flow from top to bottom (downward in the drawing) is reduced because the direction of that current corresponds to the reverse direction of this diode.

A diode allowing a current to flow from top to bottom is referred to as a forward-biased diode, and a diode allowing a current to flow in the reverse direction is referred to as a reverse-biased diode. In the diode mode, the pn junction on the anode side of a P layer in the first surface F1 side part of the depletion layer generation region 70 is reverse biased. Accordingly, carrier injection from the first surface F1 side is suppressed.

Meanwhile, the pn junction on the second surface F2 side of the depletion layer generation region 70 is forward biased. Since the carrier concentration in the P layer in the depletion layer generation region 70 is low, carrier injection on the second surface F2 side is almost suppressed.

As is apparent from the above description, the effect of suppressing carrier injection from the first surface F1 side is larger than the effect of increasing carrier injection on the second surface F2 side obtained by addition of the P layer in the depletion layer generation region 70. Therefore, the total carrier injection is reduced by the depletion layer generation region 70. Accordingly, the time until carriers are eliminated during reverse recovery of the diode can be made shorter.

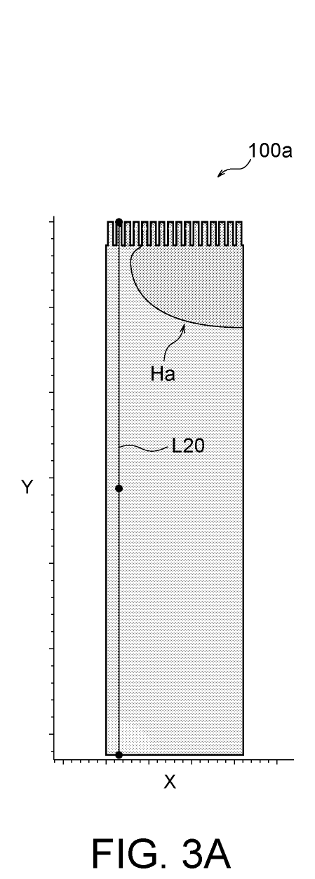

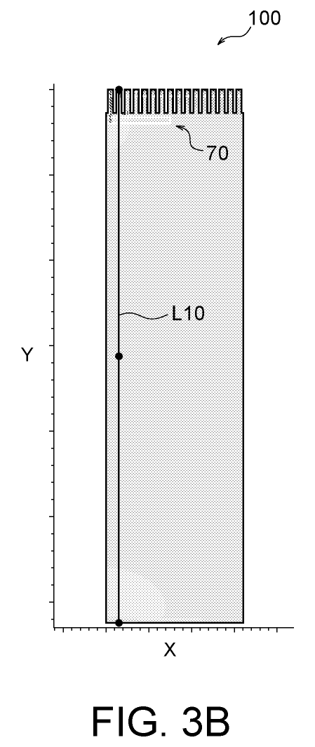

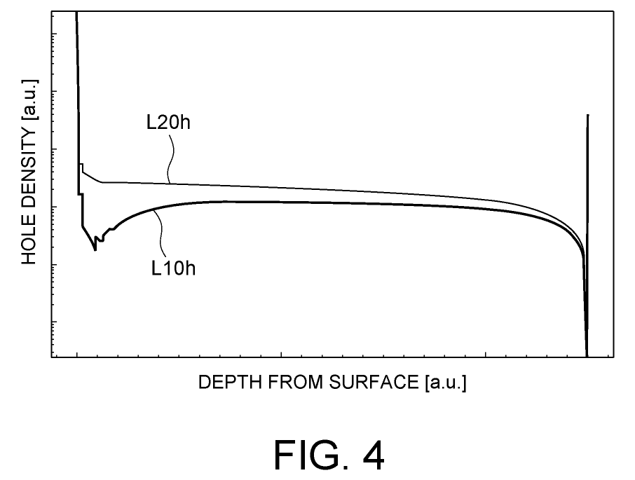

Here, the effect of the depletion layer generation region 70 of the semiconductor device 100 is described with reference to simulation results in FIGS. 3A, 3B, and 4. FIGS. 3A and 3B illustrate the second transistor region 101b and the transistor region 101 in the A-A’ cross-section in FIG. 1, obtained by simulation. FIG. 3A illustrates a case where the depletion layer generation region 70 is not included as a comparative example, and FIG. 3B illustrates a case where the depletion layer generation region 70 is included. The vertical axis represents a length from the first surface F1 to the second surface F2 by Y. The horizontal axis represents a length in the X-direction.

In FIGS. 3A and 3B, hole densities are represented by shades of color. The hole density becomes higher with increase in the concentration. In the example of FIG. 3A in which the depletion layer generation region 70 is not included, a hole region Ha with a high hole density is formed. Meanwhile, in the case of FIG. 3B in which the depletion layer generation region 70 is included, the hole region Ha with a high hole density is eliminated.

FIG. 4 indicates hole densities on lines L10 and L20 in FIGS. 3A and 3B. The horizontal axis represents a length from the first surface F1 to the second surface F2 by Y, and the vertical axis represents a hole density. Simulation at turn-off is indicated. A line L10h indicates hole densities on the line L10, and a line L20h indicates hole densities on the line L20. Also from comparison between the line L10h and the line L20h, it is found that the hole density in the case where the depletion layer generation region 70 is included is lower than that in the case where the depletion layer generation region 70 is not included.

As described above, the depletion layer generation region 70 of the second conductivity type is provided in the drift region 16 or 30 of the first conductivity type in at least either one of the second transistor region 101b and the second diode region 102b and is electrically connected to the upper electrode 12. Accordingly, during reverse recovery of the diode region 102 of the semiconductor device 100, the depletion layer generation region 70 and the drift region 16 or 30 of the upper electrode 12 of the depletion layer generation region 70 are reverse biased, and a depletion layer is generated. Accordingly, a flow of holes on the transistor region 101 side to the first diode region 102a side during reverse recovery is suppressed. Consequently, the time until carriers are eliminated during reverse recovery of the diode can be made shorter. Further, in a diode mode, the hole accumulation amount in the second transistor region 101b and the second diode region 102b that serve as a boundary region is further reduced. Therefore, recovery loss (Err) can be suppressed.

### Second Embodiment

A semiconductor device 200 according to a second embodiment is different from the semiconductor device 100 according to the first embodiment in that a potential supplied to the depletion layer generation region 70 is controlled via the third electrode 41 in the second trench GT2. Differences from the semiconductor device 100 according to the first embodiment are described below.

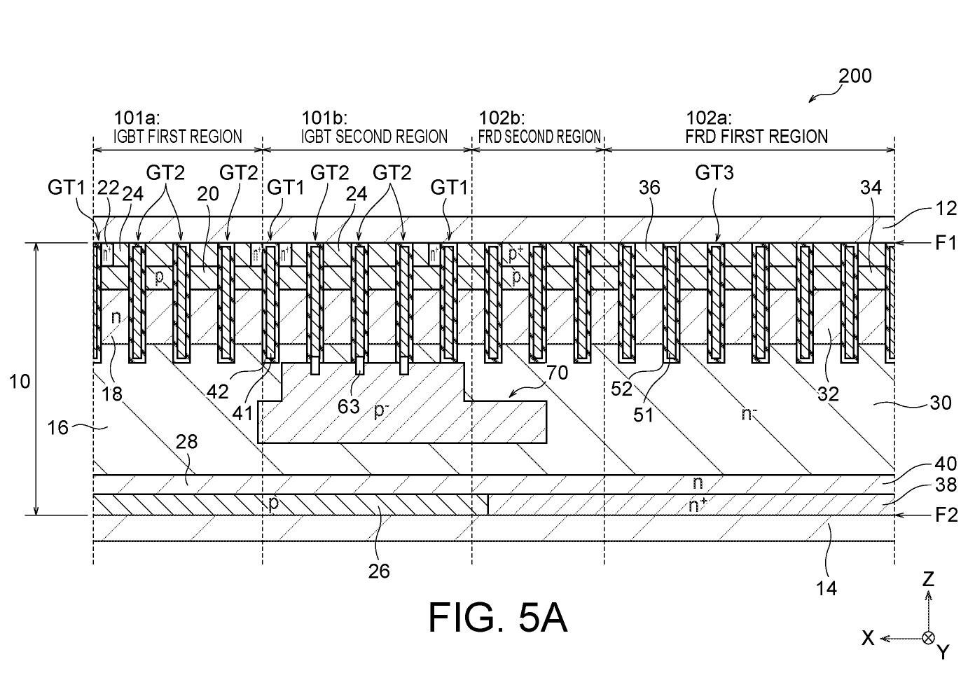

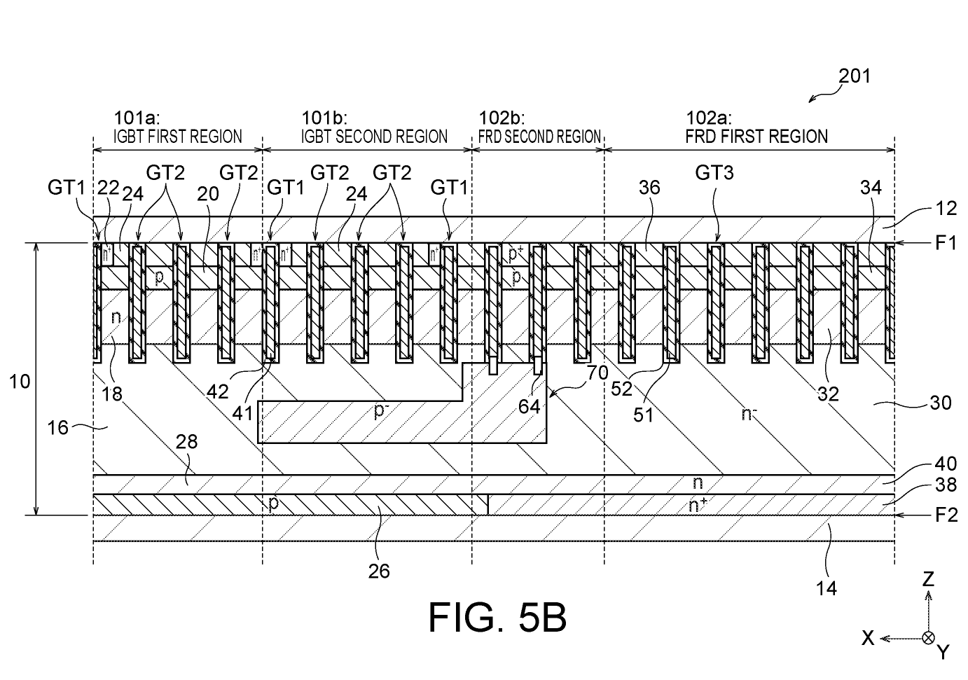

FIG. 5A is a cross-sectional view taken along the line A-A’ in FIG. 1 according to the second embodiment. As illustrated in FIG. 5A, the potential supplied to the depletion layer generation region 70 is controlled via the third electrode 41 in the second trench GT2. The third electrode 41 in the second trench GT2 and the depletion layer generation region 70 are made conductive to each other by a second contact 63 being conductive.

Further, the third electrode 41 in the second trench GT2 is electrically connected to the upper electrode 12 in a peripheral part of the semiconductor device 200. That is, the third electrode 41 in the second trench GT2 according to the second embodiment is at an emitter potential. As described above, the length of the second contact 63 can be made shorter, and the range of the potential supplied to the depletion layer generation region 70 is made adjustable.

### First Modification of Second Embodiment

A semiconductor device 201 according to a first modification of the second embodiment is different from the semiconductor device 200 according to the second embodiment in that the potential supplied to the depletion layer generation region 70 is controlled via the fourth electrode 51 in the third trench GT3 in the second diode region 102b. Differences from the semiconductor device 200 according to the second embodiment are described below.

FIG. 5B is a cross-sectional view taken along the line A-A’ in FIG. 1 according to the first modification of the second embodiment. As illustrated in FIG. 5B, the potential supplied to the depletion layer generation region 70 is controlled via the fourth electrode 51 in the third trench GT3 in the second diode region 102b. The fourth electrode 51 in the third trench GT3 in the second diode region 102b and the depletion layer generation region 70 are made conductive to each other by a third contact 64 being conductive.

Further, the fourth electrode 51 in the third trench GT3 in the second diode region 102b is electrically connected to the upper electrode 12 in a peripheral part of the semiconductor device 201. That is, the fourth electrode 51 in the third trench GT3 in the second diode region 102b according to the first modification of the second embodiment is at an emitter potential. As described above, the length of the third contact 64 can be made shorter, and the range of the potential supplied to the depletion layer generation region 70 is made adjustable.

The potential supplied to the depletion layer generation region 70 may be controlled via the third electrode 41 in the second trench GT2 according to the second embodiment together with the fourth electrode 51 in the third trench GT3 in the second diode region 102b. That is, the semiconductor device 200 according to the second embodiment and the semiconductor device 201 according to the first modification of the second embodiment may be applied to control of the potential supplied to the depletion layer generation region 70 at the same time.

### Third Embodiment

A semiconductor device 300 according to a third embodiment is different from the semiconductor device 100 according to the first embodiment in that the upper electrode 12 and the depletion layer generation region 70 are electrically connected to each other in a peripheral part of the semiconductor device 300. Differences from the semiconductor device 100 according to the first embodiment are described below.

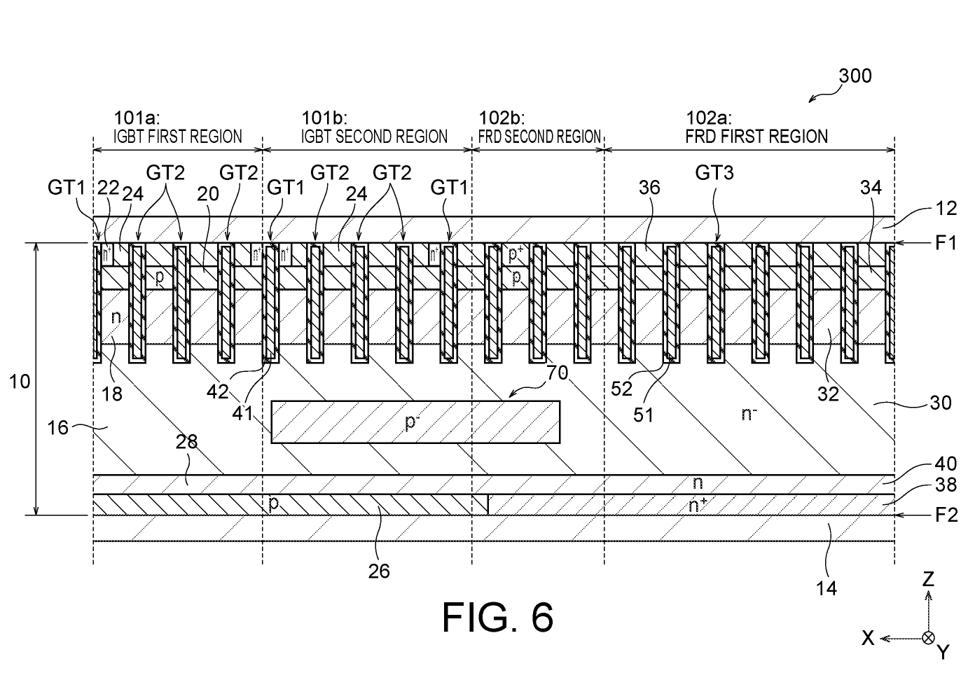

FIG. 6 is a cross-sectional view taken along the line A-A’ in FIG. 1 according to the third embodiment. FIG. 7 is a cross-sectional view taken along the line B-B’ in FIG. 1 according to the third embodiment. A cross-section including the first trench GT1 is illustrated here. A well region 152 is a p⁺-type region. The well region 152 is provided in the surroundings of the transistor region 101 and the diode region 102. As illustrated in FIG. 7, the well region 152 and the depletion layer generation region 70 are electrically connected to each other in the peripheral part of the semiconductor device 300. For example, in FIG. 1, at both ends in the X-direction of the active region part 150 in the semiconductor layer 10, the upper electrode 12 and the well region 152 are electrically connected to each other by a configuration (not illustrated), and the upper electrode 12 and the depletion layer generation region 70 are electrically connected to each other via the well region 152.

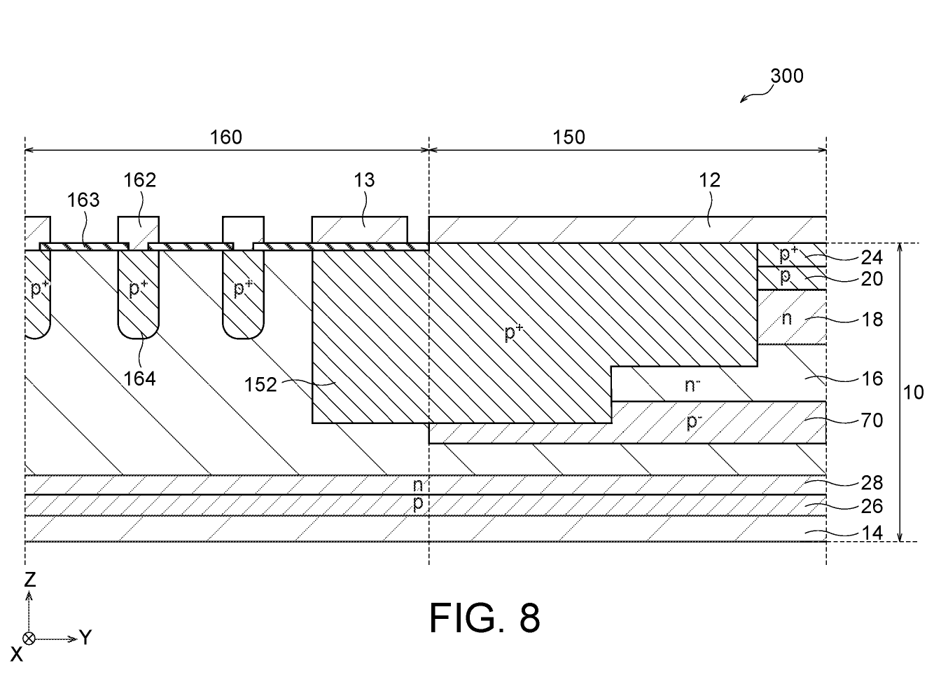

FIG. 8 illustrates an example of a cross-sectional view parallel to a B-B’ cross-section in FIG. 7. A cross-section not including the first trench GT1 is illustrated here. As illustrated in FIG. 8, it is also possible to electrically connect the upper electrode 12 and the depletion layer generation region 70 to each other at both ends in the Y-direction of the active region part 150. In FIG. 8, the upper electrode 12 and the well region 152 are in contact with each other. Although an example in which the well region 152 has a plurality of regions having different depths is illustrated in FIGS. 7 and 8, the shape of the well region 152 is not limited thereto.

As described above, a gate wire 13 is configured in the form of a ring in the peripheral region part 160 and is electrically connected to the first gate electrode pad 104 and the first trench GT1. The gate wire 13 and the semiconductor layer 10 are insulated from each other by an insulation member 163. The gate wire 13 is made of the same material as that of the upper electrode 12, for example.

A guard ring 164 is formed in the peripheral region part 160. The guard ring 164 is a p⁺-type region. By providing the guard ring 164, a depletion layer in the top surface side part of the active region part 150 can be extended outward. The guard ring 164 is electrically connected to a field plate 162. The field plate 162 is made of the same material as that of the upper electrode 12, for example.

As described above, the depletion layer generation region 70 and the upper electrode 12 can be electrically connected to each other without forming the first trench contact 60 in the semiconductor layer 10. Accordingly, the potential of the depletion layer generation region 70 can be adjusted with a simple configuration.

While certain embodiments have been described, these embodiments have been presented by way of example only, and are not intended to limit the scope of the inventions. Indeed, the novel embodiments described herein may be embodied in a variety of other forms and various omissions, substitutions, and changes may be made without departing from the spirit of the inventions. The embodiments and their modifications are intended to be included in the scope and the spirit of the invention and also in the scope of the invention and their equivalents described in the claims.

1. A semiconductor device including a transistor region and a diode region, comprising:
a semiconductor layer having a first surface and a second surface opposite to the first surface;
a first electrode provided on the first surface; and
a second electrode provided on the second surface, wherein
the semiconductor layer includes
a first region of a first conductivity type provided between the first surface and the second surface of the semiconductor layer,
a second region of a second conductivity type electrically connected to the first electrode and provided between a first surface side surface of the first region and a second surface side surface of the first region, a distance between a first surface side surface of the second region and the first electrode being longer than a distance between the first surface side surface of the first region and the first electrode,
a third region of the second conductivity type provided between the first surface side surface of the first region and the first electrode, and
a fifth region of the first conductivity type electrically connected to the first electrode and provided between the third region and the first surface.

2. The device of claim 1, wherein the second region and a portion of the first region form a pn junction, the portion of the first region being located between the second region and the first surface.

3. The device of claim 2, wherein a forward direction of the pn junction is a reverse direction to a direction from the first electrode to the second electrode.

4. The device of claim 2, wherein an impurity concentration of the second conductivity type in the second region is lower than that in the third region.

5. The device of claim 4, wherein the second region is provided within a first range having approximately a same length as a length of diffusion of holes from a boundary between the transistor region and the diode region.

6. The device of claim 5, wherein the semiconductor layer further includes a fourth region of the first conductivity type provided between the first region and the third region and having a higher impurity concentration of the first conductivity than that of the first region.

7. The device of claim 6, wherein at least a part of the first region is located between the fourth region and the second region.

8. The device of claim 2, wherein the semiconductor layer further includes
a third electrode provided in a first trench that extends from a first surface side to reach the first region and covered with an insulation film on an inner surface of the first trench, the insulation film being in contact with the third region and the fifth region, and
a first trench contact penetrating through at least the third region to reach the second region and being deeper than the first trench, and wherein
the second region is electrically connected to the first electrode via the first trench contact.

9. The device of claim 2, wherein the semiconductor layer further includes
a third electrode provided in a first trench that extends from the first surface side to reach the first region and covered with a first insulation film on an inner surface of the first trench, the first insulation film being in contact with the third region and the fifth region, and the third electrode being electrically insulated from the first electrode, and
a fourth electrode provided in a second trench that extends from the first surface side to reach the first region and covered with a second insulation film on an inner surface of the second trench, and wherein
the first trench and the second trench have a same depth as each other, and
the second region is electrically connected to the first electrode via the fourth electrode.

10. The device of claim 1, further comprising a well region provided in surroundings of the transistor region and the diode region, wherein
the second region is electrically connected to the first electrode via the well region.

11. A semiconductor device including a transistor region and a diode region, comprising:
a semiconductor layer having a first surface and a second surface opposite to the first surface;
a first electrode provided on the first surface; and
a second electrode provided on the second surface, wherein
the semiconductor layer includes
a first region of a first conductivity type provided between the first surface and the second surface of the semiconductor layer,
a second region of a second conductivity type provided between a first surface side surface of the first region and a second surface side surface of the first region, a distance between a first surface side surface of the second region and the first electrode being longer than a distance between the first surface side surface of the first region and the first electrode,
a conductive region located between the first surface and the second region, connected to the second region, and reaching the first surface,
a third region of the second conductivity type provided between the first surface side surface of the first region and the first electrode,
a fifth region of the first conductivity type electrically connected to the first electrode and provided between the third region and the first surface, and
an insulation film located between the conductive region and the third region.

12. The device of claim 11, wherein the second region and a portion of the first region form a pn junction, the portion of the first region located between the second region and the first surface.

13. The device of claim 12, wherein a forward direction of the pn junction is a reverse direction to a direction from the first electrode to the second electrode.

14. The device of claim 12, wherein an impurity concentration of the second conductivity type in the second region is lower than that in the third region.

15. The device of claim 14, wherein the second region is provided within a first range having approximately a same length as a length of diffusion of holes from a boundary between the transistor region and the diode region.

16. The device of claim 15, wherein the semiconductor layer further includes a fourth region of the first conductivity type provided between the first region and the third region and having a higher impurity concentration of the first conductivity than that of the first region.

17. The device of claim 16, wherein at least a part of the first region is located between the fourth region and the second region.

18. The device of claim 12, wherein
the semiconductor layer further includes
a third electrode provided in a first trench that extends from the first surface side to reach the first region and covered with a first insulation film on an inner surface of the first trench, the insulation film being in contact with the third region and the fifth region, and
a first trench contact penetrating through at least the third region to reach the second region and being deeper than the first trench, and wherein
the conductive region is provided in the first trench contact.

19. The device of claim 12, wherein
the semiconductor layer further includes a third electrode provided in a first trench that extends from the first surface side to reach the first region and covered with a first insulation film on an inner surface of the first trench, the first insulation film being in contact with the third region and the fifth region, and the third electrode being insulated from the first electrode, and
the conductive region is provided in a second trench that extends from the first surface side to reach the first region and that has approximately a same depth as that of the first trench.
